(19) United States
(12) Patent Application Publication
(10) Pub. No.: US 2006/0088992 A1
(43) Pub. Date: Apr. 27, 2006

(54) Bumping process and structure thereof

(75) Inventors: Min-Lung Huang, Kaohsiung (TW); Yi-Hsin Chen, Kaohsiung (TW); Jia-Bin Chen, Tainan (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaohsiung (TW)

(21) Appl. No.: 11/229,547

(22) Filed: Sep. 20, 2005

(30) Foreign Application Priority Data
Oct. 22, 2004 (TW) 93132122

(51) Int. Cl. H01L 21/44

(52) U.S. Cl. 438/614; 438/612; 438/613

(57) ABSTRACT

A bumping process is provided as following: at first, providing a wafer, then forming a first photo-resist layer on a active surface of the wafer and forming at least a first opening on the first photo-resist layer; and forming a first copper pillar in the first opening; then forming a second photo-resist layer on the first photo-resist layer and forming at least a second opening on the second photo-resist layer, wherein the second opening is bigger than the first opening so that the first copper pillar and the surrounding first photo-resist layer are exposed in the second opening; and forming a second copper pillar in the second opening; finally forming a solder layer onto the second pillar, and removing the first and second photo-resist layers.

This application claims the benefit of Taiwan application Serial No. 93132122, filed Oct. 22, 2004, the subject matter of which is incorporated herein by reference.

### BACKGROUND OF THE INVENTION

1. Field of the Invention

The invention relates in general to a semiconductor manufacturing process, and more particularly to a bumping process of wafer.

2. Description of the Related Art

In the semiconductor industry, the manufacturing process of integrated circuits (IC) is divided into three main stages: the manufacturing of wafer, the manufacturing of IC, and the package of IC. The die is manufactured according to the steps of manufacturing the wafer, performing circuit design, performing several mask manufacturing processes, and dividing the wafer. Every die formed by dividing the wafer is electrically connected to a carrier via a bonding pad disposed on the die to form a chip package structure. The chip package structure is further categorized into three types, namely, the wire bonding type, the flip chip bonding type, and the tape automatic bonding type.

Referring to FIG. 1˜FIG. 5, flowcharts of a bumping process of a conventional wafer are shown. At first, referring to FIG. 1, an under bump metallurgy 110 is formed on the entire surface of a wafer 100 and is covered up by a photo-resist layer 120. Next, referring to FIG. 2, several openings 122 are formed on a photo-resist layer 120 using the imaging technology of exposure and development, and the positions of the openings 122 correspond to several bonding pads 102 are positioned on the wafer 100. Afterwards, referring to FIG. 3, the photo-resist layer is used as a mask in copper electroplating treatment, so that the educts of copper in the electroplating solution can be adhered onto a portion of the surface using the under bump metallurgy 110 as an electroplating-seed layer to form a bump structure similar to a copper pillar 112. Next, referring to FIG. 4, the same photo-resist layer 120 is used as the mask in the solder electroplating treatment to form a mushroom-like solder layer 114 on the surface of the copper pillar 112, while the solder layer 114 which can be made of materials such as tin-lead alloy with a low melting point for instance, can therefore be reflown to be a spherical bump. Every chip (not illustrated in the diagram) of the wafer 100 is electrically connected to an external circuit board (not illustrated in the diagram) through the bump of each wafers.

At last, Referring to FIG. 5, a photo-resist layer 120 is removed, and the portion of the under bump metallurgy 110 not covered by the copper pillar 112 is etched except the portion of the under bump metallurgy 110a disposed at the bottom of the copper pillar 112. Next, the solder layer 114 is reflown so that the solder layer 114 is melted as a spherical solder bump 114a.

It is noteworthy that since the copper pillar 112 and the solder layer 114 disposed thereon are formed in the same opening 122 of the photo-resist layer 120, the depth of the opening 122 of the photo-resist layer 120 is higher than the height of the copper pillar 112, causing difficulties in exposure and development. Furthermore, the solder layer 114, after filling the opening 122 of the photo-resist layer 120, will be projected from the photo-resist layer 120, so that the two adjacent solder layers 114 are easily electrically connected to each other, causing short-circuit and affecting the reliability of subsequent packages. Besides, the spherical solder bump 114a being adhered to a lateral edge of the copper pillar precipitates the loss of copper ions.

### SUMMARY OF THE INVENTION

It is therefore an object of the invention to provide a bumping process applicable to a wafer to enhance the quality of the copper pillar and the solder layer of the electroplating manufacturing process.

It is therefore yet another object of the invention to provide a bump structure applicable to a wafer to enhance the quality of the copper pillar and the solder layer of the electroplating manufacturing process.

The invention provides a bumping process. The bumping process comprises the steps of: firstly, providing a wafer, which has several chips each having at least a bonding pad positioned on an active surface of the wafer; then, forming a first photo-resist layer on a active surface of the wafer and forming at least a first opening on the first photo-resist layer; and forming a first copper pillar in the first opening; next, forming a second photo-resist layer on the first photo-resist layer, forming at least a second opening on the second photo-resist layer, and controlling the second opening to be larger than the first opening, so that the first copper pillar and its surrounding first photo-resist layer are all exposed in the second opening; and forming a second copper pillar in the second opening; afterwards, forming a solder layer on the second copper pillar; finally, removing the first and second photo-resist layers.

According to the preferred embodiment of the invention, the above first photo-resist layer can be formed by, for example, coating a photosensitive material and forming a first opening using exposure and development. Besides, the second photo-resist layer can be formed by, for example, coating a photosensitive material and forming a second opening using exposure and development.

According to the preferred embodiment of the invention, after the formation of the wafer, the process further comprises forming an RDL and/or an under bump metallurgy on an active surface of the chip with a portion of the surface of the under bump metallurgy being exposed in the first opening. The method of forming an RDL comprises sputtering, evaporating or electroplating. Besides, in the step of forming the first copper pillar, the under bump metallurgy is used as an electroplating-seed layer and dipped in an electroplating solution for the educts of copper to be adhered onto the under bump metallurgy in the first opening. Besides, in the step of forming the second copper pillar, the under bump metallurgy is used as an electroplating-seed layer and dipped in an electroplating solution for the educts of copper to be adhered onto the first copper pillar and its surrounding first photo-resist layer which are disposed in the second opening.

The invention provides a bump structure applicable to a chip having at least a bonding pad and positioned on an active surface of the chip. The bump structure comprises a first column, a second column and a solder. The first column has a first end and a second end, and the first end connects the bonding pad. Besides, the second column is disposed on the second end, and the cross-section of the second column is larger than the cross-section of the first column. Besides, the solder is disposed on the second column.

According to the preferred embodiment of the invention, the above first column and second column form a T-shaped column for instance. The solder, which can be a spheroid or a semi-spheroid for instance, is not adhered onto a lateral edge of the second column. Besides, the above bump structure further comprises an under bump metallurgy electrically connected to between the bonding pad and the first end of the first column.

The invention adopts the first and the second photo-resist layers whose openings have different sizes to respectively form the first copper pillar and the second copper pillar in the first opening and the second opening. Besides, a solder layer can be disposed on the copper pillar of the T-shaped column. After reflowing treatment, the solder layer is not easy to be adhered onto the lateral edge of the copper pillar of the T-shaped column, effective mitigating the loss of copper ions arising when the solder layer is adhered onto the lateral edge of the copper pillar.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1˜FIG. 5 respectively are a flowchart of a bumping process of a conventional wafer.

FIG. 6˜FIG. 14 respectively are a flowchart of a bumping process according to a preferred embodiment of the invention.

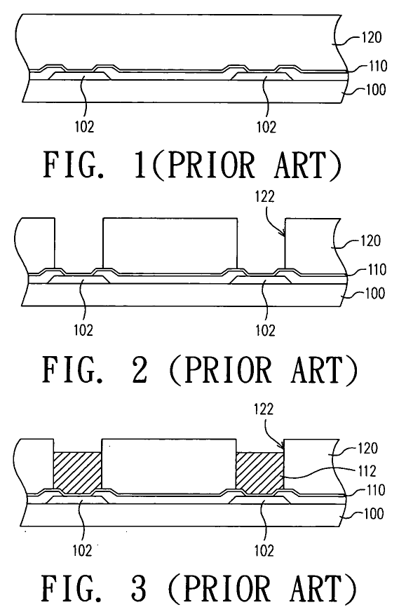

### DETAILED DESCRIPTION OF THE INVENTION

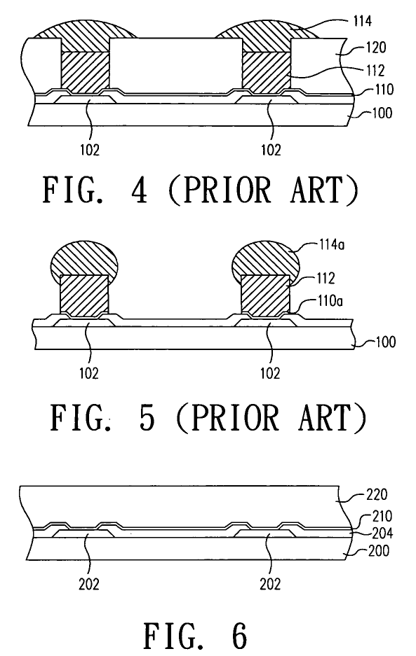

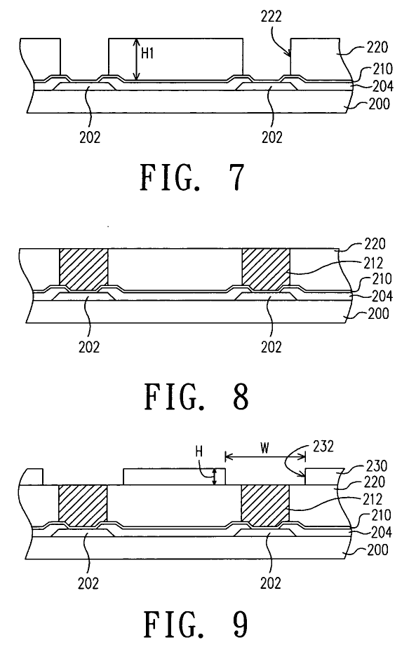

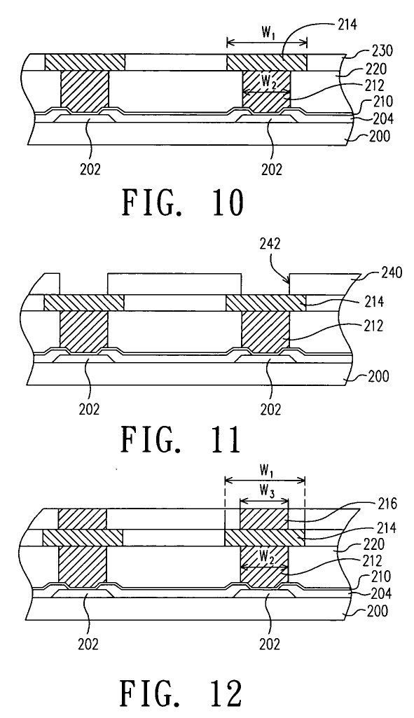

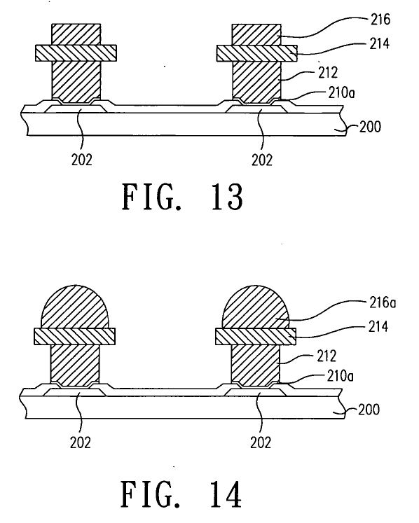

Referring to FIG. 6˜FIG. 14, flowcharts of a bumping process according to a preferred embodiment of the invention are shown. At first, referring to FIG. 6, a wafer 200 is provided, the wafer 200 has several chips (not illustrated in the diagram), and the active surface of every chip has several bonding pads 202 which are exposed in the opening of the passivation layer. Next, an under bump metallurgy (UBM) 210 is formed on the entire surface of the wafer 200, and the under bump metallurgy 210 is a multiple-layered metal layer formed by metals such as copper, nickel, vanadium, and chromium. The under bump metallurgy 210 can be formed on the surface of the wafer 200 using sputtering, evaporating or electroplating for instance, serving as a seed layer for the copper pillar and the solder layer in subsequent electroplating treatment. The present embodiment is exemplified by the electroplating manufacturing process. If the invention is embodied by non-electroplating manufacturing process, the under bump metallurgy 210 does not need to be formed on the surface of the wafer 200 beforehand. Besides, the active surface of the wafer 200, in response to the chip structure positioned at different contacting positions, can re-manufacture a re-distribution layer (RDL) (not illustrated in the diagram) and form the under bump metallurgy 210 on the RDL to proceed with the subsequent electroplating manufacturing process.

Next, a photosensitive material is coated on the under bump metallurgy 210 to form a first photo-resist layer 220.

Next, referring to FIG. 7, several first openings 222 are formed in the first photo-resist layer 220 using the imaging technology of exposure and development, wherein the first openings 222 respectively expose the under bump metallurgy 210 disposed in the bottom thereof. Next, referring to FIG. 8, the under bump metallurgy 210 is used as an electroplating-seed layer in copper electroplating treatment to form a first copper pillar 212 of appropriate height in the first opening 222. By controlling parameters such as concentration of copper ions in electroplating solution, current time/ampere and so forth, the height of the copper pillar 212 enables the educts of copper to be adhered onto the under bump metallurgy 210 and filled with the first opening 222. As shown in FIG. 7, FIG. 8, since the depth H1 of the opening of the first photo-resist layer 220 is substantially equal to a predetermined height of the first copper pillar 212, the exposure and development would have better quality producing higher resolution and accuracy.

Next, referring to FIG. 9, a second photo-resist layer 230 is formed by coating a photosensitive material. The technology of the invention differs with conventional technology in that the second photo-resist layer 230 with a larger opening of size W is formed on the first photo-resist layer 220. The second opening 232 of the second photo-resist layer 230 is also formed on the copper pillar 214 and its surrounding first photo-resist layer 220 using the imaging technology of exposure and development. That is, the size W of the second opening 232 is larger than the size of the first opening 222 disposed underneath.

Next, referring to FIG. 10, a second copper electroplating treatment is applied to the first copper pillar 212, so that a second copper pillar 214 is formed on the surface of the first copper pillar 212. The second copper pillar 214 can be a cylinder or a cuboid, the cross-section W1 of the second copper pillar 214 is larger than the cross-section W2 of the first copper pillar 212, and the two pillars are similar to a T-shaped column. In terms of structure, one end of the first copper pillar 212 is connected to the second copper pillar 214, the cross-section W1 of the second copper pillar 214 is larger than the cross-section W2 of the first copper pillar 212, and a lateral edge of the second copper pillar 214 can be projected from a lateral edge of the first copper pillar 212 preferably by 10 mil.

Next, referring to FIG. 11 and FIG. 12, a solder layer 216 is formed on the second copper pillar 214 by electroplating or printing. Take the electroplating treatment for example. The electroplating treatment can further includes forming a third photo-resist layer 240 on the second photo-resist layer 230 and forming several third openings 242 in the third photo-resist layer 240 using the imaging technology of exposure and development, and then electroplating a solder 216 in the third opening 242 to form the solder layer 216. The solder layer 216 can be made of materials such as tin-lead alloy with a low melting point or other metals. By controlling parameters such as concentration of metal ions in the electroplating solution, the height of the solder layer 216 also enables the metal educts to be adhered onto the second copper pillar 214 and filled with the third opening 242, and enables the metal educts to form a bump structure shown in FIG. 12 on every bonding pad 202 of the chip. The cross-section W3 of the solder layer 216 is smaller than the cross-section W1 of the second copper pillar 214, so that the occurrence of short-circuit between two adjacent solder layers 216 can be reduced accordingly.

Next, referring to FIG. 13, the first, the second and the third photo-resist layers 220, 230 and 240 are removed, and the portion of the under bump metallurgy 210 not covered by the first copper pillar 212 is etched except the portion of under bump metallurgy 210a disposed beneath of the first copper pillar 212. Next, the solder layer 216 of FIG. 13 is reflown to form a spherical or semi-spherical solder bump 216a as shown in FIG. 14. In the present embodiment, the solder layer 216 is not easy to be adhered onto the lateral edge of the second copper pillar 214, thus mitigating the loss of copper ions. After the bumping process of electroplating the first and the second copper pillars 212 and 214 and the solder layer 216 on the surface of the wafer 200 is completed, the wafer 200 can be divided into several independent chips (not illustrated in the diagram), and every chip can be electrically connected to an external electronic device such as a circuit board for instance via the above bump for signals to be transmitted.

It can be seen from the above disclosure that the bumping process of the invention uses multiple manufacturing processes of photoresist-coating, exposure and development to form the first and the second openings with different opening sizes on the first and the second photo-resist layers. Besides, a solder layer can be disposed on the copper pillar of the T-shaped column. After reflowing treatment, the solder layer is not easy to be adhered onto the lateral edge of the copper pillar of the T-shaped column, effective mitigating the loss of copper ions arising when the solder layer is adhered onto the lateral edge of the copper pillar. Besides, the third opening can be larger than or equal to the first opening, so that the height of the third photo-resist layer is reduced accordingly due to the use of a third opening having a larger opening so as to enhance the imaging effect. Besides, two adjacent solder layers are less likely to be short-circuited, thus enhancing the reliability of packaging.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A bumping process comprising the steps of:
providing a wafer, wherein the wafer has a plurality of chips each having at least a bonding pad positioned on an active surface of the wafer;
forming a first photo-resist layer on an active surface of the wafer and forming at least a first opening in the first photo-resist layer;
forming a first copper pillar in the first opening;
forming a second photo-resist layer on the first photo-resist layer, forming at least a second opening in the second photo-resist layer and controlling the second opening to be larger than the first opening, so that the first copper pillar and the first photo-resist layer surrounding the first copper pillar are all exposed in the second opening;
forming a second copper pillar in the second opening;
forming a solder layer on the second copper pillar; and
removing the first and the second photo-resist layers.

2. The bumping process according to claim 1, wherein after the formation of the wafer, the process further comprises forming a re-distribution layer (RDL) on the active surface of the chip.

3. The bumping process according to claim 2, wherein after the formation of the RDL, the process further comprises forming an under bump metallurgy (UBM) on the RDL with a portion of the surface of the under bump metallurgy being exposed in the first opening.

4. The bumping process according to claim 1, wherein after the formation of the wafer, the process further comprises forming an under bump metallurgy (UBM) on the active surface of the wafer with a portion of the surface of the under bump metallurgy being exposed in the first opening.

5. The bumping process according to claim 3, wherein in the step of forming the first copper pillar, the under bump metallurgy is used as an electroplating-seed layer and dipped in an electroplating solution for the educts of copper to be adhered onto the under bump metallurgy disposed in the first opening.

6. The bumping process according to claim 4, wherein in the step of forming the first copper pillar, the under bump metallurgy is used as an electroplating-seed layer and dipped in an electroplating solution for the educts of copper to be adhered onto the under bump metallurgy disposed in the first opening.

7. The bumping process according to claim 3, wherein in the step of forming the second copper pillar, the under bump metallurgy is used as an electroplating-seed layer and dipped in an electroplating solution for the educts of copper to be adhered onto the first copper pillar and the first photo-resist layer surrounding the first copper pillar are disposed in the second opening.

8. The bumping process according to claim 4, wherein in the step of forming the second copper pillar, the under bump metallurgy is used as an electroplating-seed layer and dipped in an electroplating solution for the educts of copper to be adhered onto the first copper pillar and the first photo-resist layer surrounding the first copper pillar are disposed in the second opening.

9. The bumping process according to claim 1, wherein the formation of the solder layer comprises screen-printing a solder.

10. The bumping process according to claim 3, wherein after the removal of the first and the second photo-resist layers, the process further comprises removing the portion of the under bump metallurgy not covered by the first copper pillar.

11. The bumping process according to claim 4, wherein after the removal of the first and the second photo-resist layers, the process further comprises removing the portion of the under bump metallurgy not covered by the first copper pillar.

12. The bumping process according to claim 1, wherein after the removal of the first and the second photo-resist layers, the process further comprises reflowing the solder layer.

13. A bump structure applicable to a chip, wherein the chip has at least a bonding pad positioned on an active surface of the chip, the bump structure comprising:
a first column having a first end and a second end, wherein the first end connects the bonding pad;
a second column disposed on the second end, wherein the cross-section of the second column is larger than the cross-section of the first column; and
a solder disposed on the second column.

14. The bump structure according to claim 13, wherein the first and the second columns form a T-shaped column.

15. The bump structure according to claim 13, wherein the radius of the cross-section of the second column is larger than that of the cross-section of the first column 10 mil.

16. The bump structure according to claim 13, wherein the first column and the second column comprise cylinders.

17. The bump structure according to claim 13, wherein the material of the first column and the second column comprise copper.

18. The bump structure according to claim 13, wherein the solder the material comprises tin.

19. The bump structure according to claim 13, wherein the solder is not adhered onto a lateral edge of the second column.

20. The bump structure according to claim 13, further comprises an under bump metallurgy electrically connected between the bonding pad and the first end of the first column.
